(19) United States
(12) Patent Application Publication
(10) Pub. No.: US 2017/0110869 A1
(43) Pub. Date: Apr. 20, 2017

(54) ELECTRICAL MEASURING DEVICE FOR MEASURING THE RESISTANCE OF AN EARTH CONNECTION OF AN ELECTRICAL FACILITY

(71) Applicant: ELECTRICITE DE FRANCE, Paris (FR)

(72) Inventor: Jean-Luc Bargues, Les Clayes Sous Bois (FR)

(21) Appl. No.: 15/110,588

(22) PCT Filed: Jan. 8, 2015
(86) PCT No.: PCT/FR2015/050043

§ 371 Date: Sep. 22, 2016

(30) Foreign Application Priority Data
Jan. 8, 2014 (FR) 14 50137
Jan. 8, 2014 (FR) 1450136

(51) Int. Cl. H02H 1/00; G01R 19/02; H02H 5/10; G01R 27/20

(52) U.S. Cl. CPC H02H 1/003; G01R 27/20; G01R 19/02; H02H 5/105

(57) ABSTRACT

An electrical measuring device for measuring the resistance of an earth connection of an electrical facility. The device comprises at least: a first link to an earth connection of the masses of an electrical facility; a second link to a neutral conductor; an alternating current generator; and a control unit suitable for: instructing the generator to inject alternating current into the earth connection of the masses; measuring, between said first and second links, a voltage generated by said injected current; determining a resistance of the earth connection of the masses according to the injected current and the measured voltage; and emitting a first warning signal when said compared resistance exceeds said pre-determined threshold.

### CROSS-REFERENCE TO RELATED APPLICATIONS

This application is the U.S. national phase of the International Patent Application No. PCT/FR2015/050043 filed Jan. 8, 2015, which claims the benefit of French Application No. 14 50137 filed Jan. 8, 2014, and of French Application No. 14 50136 filed Jan. 8, 2014, the entire contents of all are incorporated herein by reference.

### FIELD

The invention relates to the field of electrical systems of electrical power distribution networks, and in particular to devices for measuring the resistance of the earth connection for the exposed conductive parts of the electrical system. The invention further provides an electrical measuring method for monitoring the evolution of the earth connection of the electrical system and for issuing an alert when the earth connection for the exposed conductive parts no longer protects people appropriately.

### BACKGROUND

For reasons of electrical safety, in particular to protect people from indirect electrical contact (shocks or electrocution) and to protect equipment in case of an electrical malfunction, electrical facilities with TT earthing systems have an earth connection for the exposed conductive parts.

The simplest expression of such an earth connection is a metal part that is driven into the ground to ensure an effective electrical bond with the earth (for example a metal stake planted in the ground, or buried metal cables). Due to the intrinsic electrical properties of the earth, the earth connection constitutes a reference potential in the electrical system which is used in particular for the flow of electrical loads from the system such as fault current loads.

By definition, a fault current can be generated by an electrical fault in the system (such as a localized insulation fault, for example). The fault current then flows through the earth connection and can be detected by a protective means associated with the earth connection (such as a residual current device (RCD) for example). In a known manner, if the value of the fault current exceeds a predetermined threshold, the breaker then transitions to a “tripped” position (opening the electric circuit) to prevent electrical hazards.

The cooperation between the earth connection and a residual current device thus prevents dangerous increases in the potential of conductors that may be touched by an individual.

However, for effective protection of electrical system equipment and users, the earth connection for the exposed conductive parts should be properly calibrated. For this reason and to comply with current legislation (NFC 15-100 or IEC 60364 standards for example), the electrical resistance of the earth connection for the exposed conductive parts must not exceed a well defined threshold resistance. This threshold resistance is based on the type of power (an alternating current AC) and the surrounding humidity conditions.

As an example, in France it is considered that in dry areas, the maximum voltage when there is indirect contact with an individual (following an appliance insulation fault for example) must be 50 V AC, with a maximum fault current of 0.5 A (which is usually the rated current of the residual current device (NFC 14-100) associated with the earth connection for the exposed conductive parts). In fact, the resistance of the earth connection must not exceed a resistance threshold of 100Ω.

At present, when newly constructed buildings are about to be delivered, the resistance of the earth connection for the exposed conductive parts is tested beforehand to ensure that the electrical system complies with legislation and provides good electrical protection.

However, this testing does not inform us of variations over time in the resistance of the earth connection for the exposed conductive parts. The value of this resistance is impacted by various parameters which can fluctuate, such as:
aging of the component materials of the earth connection,
degradation or breakage of the mechanical connection of the earth connection to the electrical system,
changes in humidity levels (from water damage, for example), and/or
electrochemical phenomena at the edges of the earth connection.

Fluctuations in these parameters may lead in particular to exceeding the resistance threshold of the earth connection (100Ω to use the example cited above). The electrical system then becomes dangerous, particularly for third parties who may be exposed to electrical shocks and/or electrocution when the voltage exceeds 50 V AC.

There is therefore a need to implement a solution for monitoring the changes over time in the earth connection for the exposed conductive parts, in order to ensure the electrical safety of the electrical system for the long term and ensure that it does not present any electrical hazard to users as it ages.

The earth connection can be regularly monitored using known portable devices for performing an isolated measurement of the earth connection for the exposed conductive parts.

For example, there are portable devices for testing the earth connection which can be plugged into or electrically connected to an electrical outlet of an electrical system in order to determine an overestimated current value of the earth connection for the exposed conductive parts, and intrinsically to verify the continuity of the protective conductor of the electrical outlet used, all the way to the earth electrode. With this type of measurement (only possible in a TT earthing system), the resistance obtained from a measurement is a cumulative resistance of the earth connection for the exposed conductive parts and for the transformer neutral. As the resistance of the earth connection for the transformer neutral is relatively low, the resistance measurement obtained is therefore considered to correspond to an overestimated current value of the earth connection for the exposed conductive parts.

As another example, devices also exist for measuring the earth connection which require disconnecting the earth connection for the exposed conductive parts of the electrical system, and planting stakes in the ground near the earth connection for the exposed conductive parts. The planted stakes allow injecting current and measuring potentials to determine the current resistance of the earth connection for the exposed conductive parts.

That being said, these devices are only designed for conducting spot checks of the earth connection for the exposed conductive parts. They also have the drawbacks of requiring:
occupying an outlet socket of the electrical system (possibly requiring that an electrical appliance be unplugged to perform the check), or
restrictive setup operations for each measurement (the earth connection of the electrical system must be disconnected, the earth connection for the exposed conductive parts is often difficult to access, and it is not always possible to plant the stakes in the ground (for example in urban areas)); and
the above inconveniences recur with each new measurement.

In addition, the power cord and/or the plug of an electrical appliance may be damaged, resulting in a possible discontinuity in the protective conductor, which can result in the circuit breaker not tripping and the subsequent appearance of dangerous insulation fault voltage from the appliance. The user is then exposed to the risk of electrocution during indirect contact with such an electrical appliance.

There is therefore a need for a sustainable solution for measuring the earth connection for the exposed conductive parts which overcomes the disadvantages of the prior art.

### SUMMARY

The present invention improves the situation.

The invention provides an electrical measuring device which regularly or continuously measures the resistance of the earth connection for the exposed conductive parts, in order to accurately monitor its evolution (i.e. the state of the earth connection for the exposed conductive parts, as it ages). The proposed device and method also alert a user and/or an operator when an electrical hazard is established from the measured value of the earth connection for the exposed conductive parts.

To this end, a first aspect of the invention relates to an electrical measuring device which comprises at least:
a first electrical connection to an earth connection for the exposed conductive parts of an electrical system connected to a power network (referred to hereinafter as the “main power network”);
a second electrical connection to a neutral conductor of the main power network;
an alternating current generator regulated and controlled so as to inject alternating current into the first electrical connection;
a control unit adapted for:
   instructing the generator to inject regulated alternating current into the earth connection for the exposed conductive parts via the first connection;
   measuring, between the first and second connections, a voltage generated by the injected current;
   determining a resistance of the earth connection for the exposed conductive parts, based on at least one injected current value and on a voltage value measured for the injected current value;
   comparing the determined resistance to a predetermined threshold; and
   issuing a first warning signal when said compared resistance exceeds the predetermined threshold.

In this case, the voltage generated between the first and second connections can be measured:
by an instantaneous potential difference for the peak values of the injected current when the latter is a sinusoidal alternating current, or
by a true RMS voltage.

Regular measurements (for example daily or weekly) or continuous measurements may be performed on the earth connection for the exposed conductive parts without requiring installation operations (disconnecting the earth connection, planting stakes, etc.), unplugging the appliance, or monopolizing an electrical outlet of the electrical system for each measurement.

The measuring device warns when a predetermined threshold is exceeded. A user or operator can be warned by the issued alert notifying of an inappropriate value of the resistance of the earth connection for the exposed conductive parts, a value that could lead to a hazardous situation for users.

The device therefore makes it possible to closely monitor variations over time in the earth connection for the exposed conductive parts, and variations in the connection of the appliance to this earth connection, and to alert a user or operator the moment the earth connection for the exposed conductive parts is no longer in a safe state (i.e. the resistance is within a safe range). With this close surveillance, rapid detection of a fault is possible. Maintenance can then be swiftly carried to repair the link to the earth connection for the exposed conductive parts or to test and possibly construct a new earth connection for the exposed conductive parts and thus return its value to below the predetermined threshold. The safe range may be based in particular on the requirements defined by standards NFC 15-100 and/or IEC 60364.

It is understood that the device ensures the electrical safety of the appliance, the user, and the electrical system for the long term.

The device is suitable for installation in a low-voltage electrical system having a TT earthing system.

It can equip an electrical appliance connected to the electrical system such as a television, computer, washing machine, refrigerator, or an electrical panel of the system.

Advantageously, the device may further comprise a switch to cut off power to an electrical appliance plugged into the electrical system, the control unit being adapted to open the switch when the compared resistance exceeds the predetermined threshold.

The electrical appliance in question may be a device plugged into the electrical system or the electrical panel of the system.

In the open position, the double-pole switch opens the single-phase power circuit. The electrical appliance is then no longer supplied with power. If this appliance has an insulation fault, the exposed conductive parts of this appliance or of the electrical system are no longer receiving power from the active conductors (phase or neutral), thus eliminating any risk of electrocution or electric shock from the appliance.

Because it is installed or delivered with the electrical appliance, the measuring device is implanted directly in the electrical system, in a fixed manner. The evolution of the connection of the appliance to the earth connection for the exposed conductive parts of the system is monitored to ensure that the appliance remains properly connected. This monitoring allows:
tracking the evolution over time of the earth connection of the electrical system,
ensuring the integrity of the connection between the electrical appliance and the earth connection (typically the integrity of the plug and/or the power cord of the appliance, including the power, neutral, and protective conductors).

User safety is therefore increased, because the appliance is only supplied power if the resistance of the earth connection for the exposed conductive parts of the electrical system allows protecting people from dangerous electrical hazards (otherwise the power to the device is cut off by the switch which is then set to the open position).

In an advantageous embodiment, the device may further comprise an autonomous source of electrical power.

Power may be drawn upstream of the double-pole switch to allow the device to recharge the battery backup for when power to the device is lost and thus continue to operate, generating a warning signal. In addition, when the switch opens which cuts off power to the appliance, the device issues a warning signal.

Advantageously, the injected current is regulated over time at least at a first level of current and a second level of current which are successively injected, the first and second levels of current being different.

Injection of current at two different levels provides a more accurate value for the overall resistance. By injecting different levels of current, the voltage levels generated by these currents allow, by differentiating them, ignoring the resistance of the neutral conductor. The resistance measurement is therefore more accurate, concerning only the resistance of the earth connection for the exposed conductive parts and the resistance of the earth connection to neutral (the latter being very low or even zero).

In an advantageous embodiment, the device may further comprise a third electrical connection to a phase conductor of the network. The control unit may be further adapted for:
measuring the true RMS voltage between the second and third connections;
comparing the true RMS voltage to a required voltage range; and
issuing a second warning signal when the true RMS voltage is not within said required voltage range.

In particular, the required voltage range may be between 200 volts and 250 volts.

The control unit can then stop the voltage measurements and issue an alert, in particular to propose the intervention of an operator of the electric power distribution network in order to restore the voltage expected by the device. The control unit then proceeds with the voltage measurements once the electrical conditions allow stable current injections by the generator.

In addition, the device may further comprise nonvolatile memory adapted for storing data such as data relating to the predetermined threshold, the measured voltage, said measured true RMS voltage, and/or the determined resistance.

The predetermined threshold data and the measured voltage values and the determined resistance values are thus stored in the device in a lasting manner.

In an advantageous embodiment, the resistance compared to the predetermined threshold may be an average resistance of the earth connection for the exposed conductive parts, calculated by the control unit from data stored in memory. The memory may further be adapted to store data relating to the average calculated resistance value.

According to this embodiment, the determined average value may be based on the resistance values measured at well-defined moments. This average is a value representative of the state of the earth connection for the exposed conductive parts over a given period of time. This weighted average allows incorporating any calculated resistance values that are non-homogeneous due to a possible instability observed in the measured voltages between the neutral conductor and the earth, because the injected current is considered stable if the generator maintains the current below said required voltage range (which may be between 200 volts and 250 volts).

Typically, the average value can be a weighted average of the resistance values measured every hour for a day. The obtained average is then representative of the state of the earth connection for the exposed conductive parts, for the day in question.

The average value can be compared to the predetermined threshold to determine whether the resistance of the earth connection for the exposed conductive parts, over a given period of time, is in a state that is generally appropriate for the electrical system or whether it requires issuing an alert to warn of a hazardous situation.

The saved average value therefore provides a good representation of how the earth connection for the exposed conductive parts evolves over time, without requiring that a large number of measured values be processed during each post-processing of archived data.

In one possible embodiment, the data stored in the device may be timestamped when they are stored in memory.

In this embodiment, the stored and timestamped data can be used in post-processing or by the control unit to create a history of measurements and to track variations in the voltages and resistances measured over time in the earth connection for the exposed conductive parts.

The predetermined threshold may be an electrical resistance value of between 25 and 100Ω.

In this embodiment, the electrical resistance can thus be determined according to the requirements of standard NFC 15-100 (or European standard IEC 60364). Typically, the predetermined threshold value is:
for an electric power network in France providing AC power:
   100Ω when the environment of the low voltage electrical system is dry,
   50Ω when the environment of the low voltage electrical system is wet,
   25Ω when the environment of the low voltage electrical system is submerged,
For an electric power network in France providing DC power:
   240Ω when the network environment is dry,
   120Ω when the network environment is wet,
   60Ω when the network is submerged.

For added security, the predetermined threshold may be initialized to a value slightly below the limits prescribed by the standard, for example 5% lower than the above values.

In any event, it should be noted that the predetermined threshold value may be initialized to a value exceeding 100Ω (800Ω for example in Spain with an IΔn 30 mA circuit breaker), provided that this resistance value does not expose a user to voltage exceeding 50 volts with an IΔn 500 mA circuit breaker, in case of indirect contact.

In an advantageous embodiment, the device may further comprise a communication unit for transmitting the first and/or second issued warning signal to a remote entity.

In this manner, the measuring device can issue warning signals to a remote entity such as a management center or a communicating device of a user such as a mobile phone (typically a smartphone). Then, when a hazardous situation is detected or when the voltage supplied to the measuring device is outside the required range, the notice is sent directly to the management center or user so that the earth connection for the exposed conductive parts can quickly be repaired or replaced, or appropriate power can be restored to the device (typically a voltage of about 230 volts). The safety of individuals is thus further improved.

In addition, the communication unit may also be able to transmit data stored in said memory when so requested.

Thus, the determined resistance data, the measured voltages data, and/or the predetermined threshold value may be transmitted at the request of a remote entity or of a user (via an application on the smartphone, for example). These communicated data allow deployment of services such as remotely monitoring for earthing faults in the device and its power supply.

Additionally or alternatively, the device may further comprise a local alarm module emitting a signal when one among the first and second warning signals is issued.

Typically, the local alarm module may comprise:
a speaker emitting an audio signal when it is detected that the predetermined threshold is exceeded and/or that the device is not receiving a voltage within the required voltage range; and/or
a light source such as an LED emitting for example a light signal that is:
   green when the resistance of the earth connection for the exposed conductive parts is substantially constant and is below the predetermined threshold;
   red when it is detected that the predetermined threshold is exceeded and/or that the device is not receiving a voltage within the required voltage range; and
   orange when the resistance of the earth connection for the exposed conductive parts is below the predetermined threshold but is trending upward.

The electrical measuring device may further comprise a display screen showing the nature of the alert when a warning signal is issued, and possibly the date and time at which the warning signal was issued. The display screen may also show the latest average resistance and network voltage.

In a second aspect, the invention relates to a home appliance plugged into an electrical system connected to a main power network, said system being provided with an earth connection for the exposed conductive parts. The appliance is connected to the earth connection for the exposed conductive parts and is equipped with an electrical measuring device as described above. This appliance may be equipment such as a television, computer, washing machine, refrigerator, or other equipment, or an electrical panel of the electrical system.

According to a third aspect, the invention relates to a method for electrical measurement by means of an electrical measuring device. The method comprises at least the steps of:
a) injecting regulated alternating current into an earth connection for the exposed conductive parts of an electrical system connected to a main power network;
b) measuring, between the earth connection for the exposed conductive parts and a neutral conductor of the network, a voltage generated by the injected current;
c) determining a resistance of the earth connection for the exposed conductive parts, based on at least one injected current value and a voltage value measured for the injected current value;
d) comparing the determined resistance to a predetermined threshold; and
e) issuing a first warning signal when the measured resistance exceeds the predetermined threshold.

Advantageously, the method may further comprise a step of cutting off the power to an electrical appliance plugged into the electrical system, when the compared resistance exceeds said predetermined threshold.

In an advantageous embodiment, the resistance compared to said predetermined threshold is a weighted average value calculated from measured resistance values of the earth connection for the exposed conductive parts.

In an advantageous embodiment, the current injection step comprises a regulation of the current over time at least at a first level of current and a second level of current which are successively injected, the first and second levels being different.

Advantageously, the method may additionally comprise the steps of:
measuring a true RMS voltage between the neutral conductor and a phase conductor of the network;
comparing the true RMS voltage to a required voltage range; and
issuing a second warning signal when the true RMS voltage is not within the required voltage range.

The method may further comprise:
a step of initializing the threshold according to an electrical resistance value, and
a step of storing data relating to the threshold in nonvolatile memory.

Additionally or alternatively, the method may further comprise a step of timestamping and storing in memory the data relating to the measured voltage and the determined resistance.

Advantageously, in the comparison step, the resistance compared to the predetermined threshold is an average resistance value of the earth connection for the exposed conductive parts, calculated by the control unit using data stored in memory.

Additionally, the method may comprise a step of communicating the first and/or second issued warning signal to a remote entity.

In an advantageous embodiment, steps a) and b) may be successively repeated at a first frequency, step c) may be repeated at a second frequency, steps d) and e) may be successively repeated at a third frequency. In this embodiment, the first, second, and third frequencies may respectively have decreasing frequency values.

Typically, the first frequency may be a so-called high and regular frequency (every 500 ms, for example), or even continuous.

The second frequency may be a frequency such that the weighted average value of the resistance of the earth connection for the exposed conductive parts is calculated at regular intervals (typically every minute or every hour) using the resistance values calculated for the period concerned. This weighted average allows incorporating any calculated resistance values that are non-homogeneous due to a possible instability observed in the measured voltages between the neutral conductor and the earth, because the injected current is considered stable if the generator is operating below said required voltage range.

As for the third frequency, it may be a frequency suitable for monitoring the evolution over time of the earth connection for the exposed conductive parts, for example such as daily or weekly. This lower frequency may be suitable for calculating the differences between two weighted averages for a day, week, or month, and for determining a possible increase in the earth connection resistance over this period.

According to a fourth aspect, the invention further relates to a computer program intended to be stored in a memory of an electrical measuring device. This computer program comprises instructions readable by a processor of a control unit of the device, the processor implementing the method described above when said instructions are executed by the processor.

### BRIEF DESCRIPTION OF THE DRAWINGS

Other features and advantages of the invention will become apparent upon examining the following detailed description and the attached figures in which:

FIG. 1a represents an example of an electrical system comprising an electrical appliance incorporating the electrical measuring device according to the invention;

FIG. 1b represents an example of an electrical system comprising a low voltage electrical panel incorporating the electrical measuring device according to the invention;

FIG. 2a represents a first embodiment of the electrical measuring device;

FIG. 2b represents a second embodiment of the electrical measuring device;

FIG. 3a is a flowchart representing a first example of the sequence of steps of the electrical measuring method according to the invention;

FIG. 3b is a flowchart representing a second example of the sequence of steps of the electrical measuring method according to the invention.

For reasons of clarity, the dimensions of the various components represented in these figures are not necessarily in proportion to their actual dimensions. In the figures, identical references correspond to identical elements in the different embodiments described.

### DETAILED DESCRIPTION

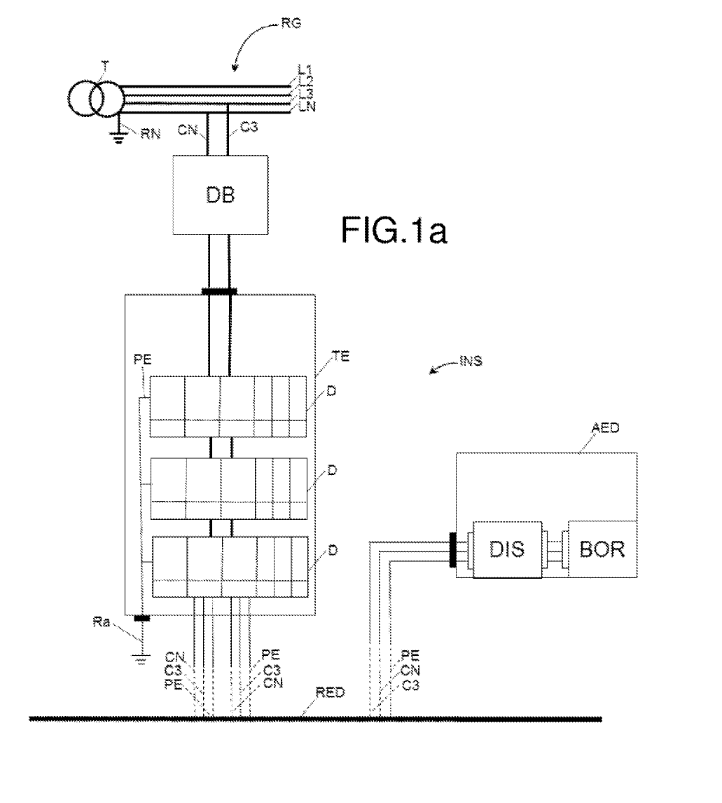

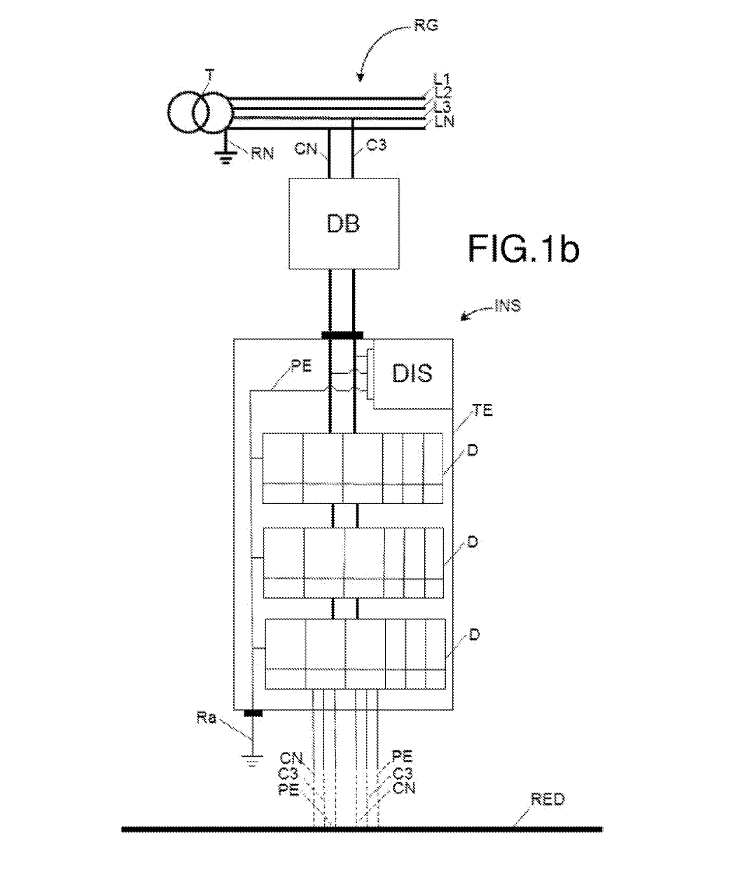

We first refer to FIG. 1a, which illustrates an exemplary embodiment of the electrical measuring device DIS equipping a household appliance AED of a low voltage electrical system INS connected to a main power network RG distributing three-phase AC power, 230/400 V, 50 Hz, with a single-phase connection. This assembly forms a low voltage electrical system in which the device DIS is incorporated into the appliance AED

The appliance AED is an appliance operating on power supplied by a low voltage residential power network RED. Such an appliance may be a household appliance (refrigerator, washing machine, dryer, etc.) or any other electric household equipment (hot water system, radiators, air conditioning, etc.).

The panel TE is provided for receiving electric power from a distribution transformer T or other facility of an electric power distributor.

The distribution transformer T here is a three-phase transformer in a star configuration with accessible neutral point, feeding electrical conductors L1, L2, L3, and in which the accessible neutral point is connected to the earth connection of the neutral RN used as a neutral reference point with the neutral conductor LN of the network RG.

The power distribution network RG is arranged according to a TT earthing system. Thus, the neutral of the distribution transformer T is connected to ground via the earth connection of the neutral RN and, as detailed below, the exposed conductive parts of the electrical equipment plugged into the residential power network RED, such as the appliance AED, have their own connection to the earth connection for the exposed conductive parts Ra of the electrical system INS via conductor PE. The panel TE is therefore connected:
to the neutral of the distribution transformer T via a neutral conductor CN connected to the electrical conductor LN;
to its own earth connection for the exposed conductive parts Ra, via conductor PE; and
via a phase conductor C3, to a conductor of the network RG supplied by the transformer T (such as conductor L3).

The power received by the panel TE from the transformer T is then distributed to different branches of the residential power network RED. To this end, the panel distributes power to conductors C3, CN, and PE in the residential network RED in order to supply the electrical appliances plugged into it.

A main disconnect circuit breaker DB (typically a residual current device (RCD) with a rated current of 500 mA, noted IΔn 500 mA) may be arranged upstream of the low voltage electrical panel TE to protect the distribution transformer T, the low voltage electrical panel TE, and the residential network RED in case of failure.

The panel TE is arranged at the front of the residential network RED and allows supplying power in a safe manner to the various lines downstream in the network RED, via circuit breakers D. In this example, the circuit breakers are organized into rows of breakers. The circuit breakers D may be residual current devices (RCD) rated for protecting their associated lines from electrical damage (such as overload or short circuits). Typically, the circuit breakers of a residential panel TE have a rated current of 30 mA (in other words IΔn 30 mA).

The lines they protect may consist of the phase conductor C3, the neutral conductor CN, and the earth conductor PE. Conductor PE is connected to the earth connection for the exposed conductive parts Ra of the electrical system INS.

Typically, the earth connection for the exposed conductive parts Ra of the electrical system INS may be implemented in the form of:
metal stakes driven into the ground,
metal cables buried in the ground,
metal plates,
concrete reinforcements embedded in the ground,
or other.

This earth connection is usually in the building equipped with the electrical system INS, or is nearby.

The lines downstream of the panel TE supply power to the residential power network RED and to the electrical devices (not represented in the figures) plugged into it. The devices are connected to the neutral via conductor CN of the corresponding line, to the power via conductor C3, and to the earth via conductor PE of the same line.

For the circuit breakers D to provide the expected protection on the lines associated with them, and to prevent individuals such as consumers from exposure to dangerous indirect contacts, the resistance of the earth connection should not exceed a safety threshold value. For example, the NFC 15-100 standard states that the resistance of the earth connection must not exceed 100Ω if the network RED is providing AC power in dry conditions.

By means of the network RED, the appliance AED is also connected:
to the neutral of the distribution transformer T via a neutral conductor CN connected to conductor LN;
to the earth connection for the exposed conductive parts Ra of the electrical system INS via conductor PE; and
via the phase conductor C3, to a conductor of the network RG supplied by the transformer T (such as conductor L3).

In the example represented for purely illustrative purposes, power received by the appliance AED is therefore single-phase. To obtain three-phase power, the appliance AED may be provided with additional conductors respectively connected to conductors L1 and L2 via the network RED and the panel TE.

The appliance AED incorporates the electrical measuring device DIS which allows monitoring the earth connection for the exposed conductive parts Ra and link PE.

It should be noted that the appliance AED may incorporate the device DIS in situ or may be equipped with such a device. If the appliance AED is equipped with the device DIS, the appliance AED is arranged so that the device is connected to at least:
the earth connection for the exposed conductive parts Ra via the connection to conductor PE,
conductor CN, and
conductor C3.

The phase and neutral conductors may be cross-connected in the outlet receptacle or junction box that supplies the device. These same conductors may also be cross-connected in the power cord plug or in the terminal block of the appliance. Also, the device DIS may be provided with a reversing switch which supplies the generator GEN. The control unit UC sets this reversing switch to a first position if a voltage close to the nominal voltage (230 volts, for example) is measured between conductors C3 and PE. Otherwise, the unit CU sets the switch to position 2.

It is understood that the device DIS equipping the appliance may therefore, according to some possible embodiments, be installed on the appliance AED externally to the housing of the appliance AED or near the appliance while being connected to the appliance via a dedicated line, or be interfaced between the network RED and the power cord of the appliance, or be arranged on the power cord of the appliance.

In the example represented in FIG. 1a, the device DIS is incorporated into the appliance AED, placed between the network RED and the terminal block BOR of the appliance AED.

We now refer to FIG. 1b in which is illustrated an exemplary embodiment of the electrical measuring device DIS equipping the low-voltage electrical panel TE of an electrical system INS connected to a main power network RG distributing three-phase AC power, 230/400 V, 50 Hz, with single-phase connection (a phase and a neutral). This assembly forms a low voltage electrical system where the device DIS is incorporated into the panel TE.

In the example represented for purely illustrative purposes, the power received by the panel TE is therefore single-phase. To obtain three-phase power, the panel TE may be provided with additional conductors respectively connected to conductors L1 and L2.

The panel TE incorporates the electrical measuring device DIS to monitor the resistance of the earth connections Ra, RN and of the neutral conductor. The device DIS comprises a connection to conductor PE.

Note that the panel TE may incorporate the device DIS in situ or may be equipped with such a device. If the panel TE is equipped with the device DIS, the panel TE is arranged so that the device is connected to at least:
the earth connection for the exposed conductive parts Ra via the connection to conductor PE,
conductor CN, and
conductor C3.

It is understood that the device DIS equipping the panel may therefore, in one possible embodiment, be installed on the panel TE externally to the panel box or near the panel while being connected to the panel via a dedicated line.

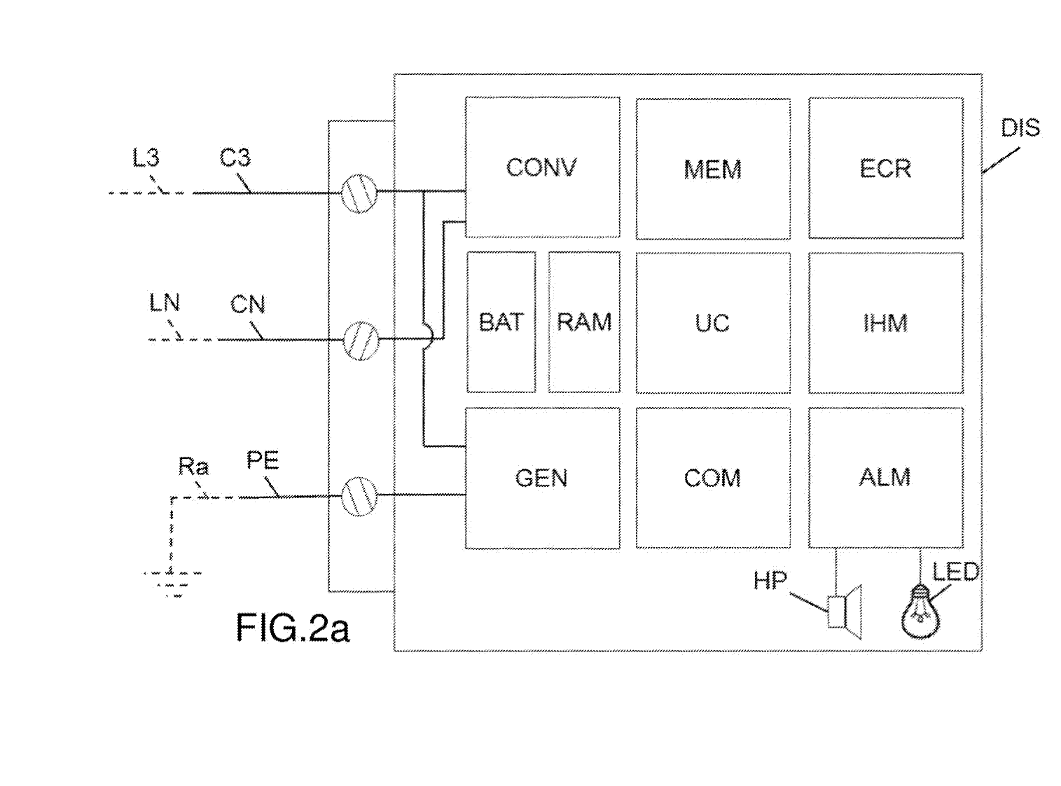

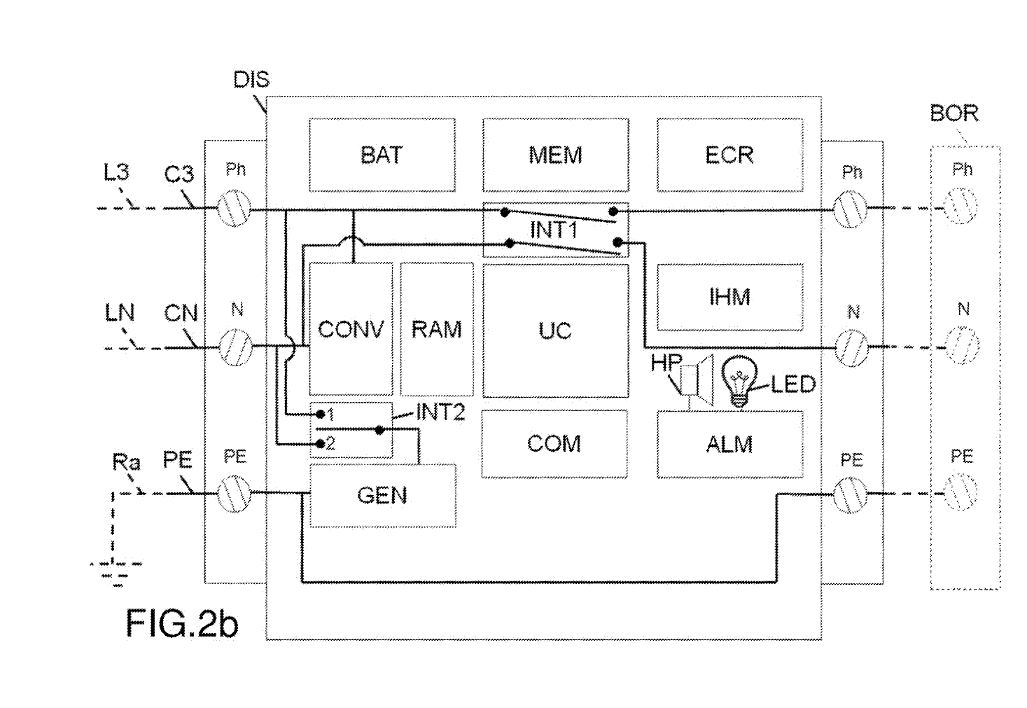

We now refer to FIG. 2a in which a first exemplary embodiment of the device DIS is represented.

The device DIS has connections to the earth connection for the exposed conductive parts Ra, to the neutral conductor LN of the network RG, and to a phase conductor L3 of the network RG, via electrical connections such as:
a conductor PE connected to the earth connection for the exposed conductive parts Ra of the electrical system INS,
a neutral conductor CN connected to the neutral conductor LN of the network RG;
a phase conductor C3 connected to the phase conductor L3.

The device DIS further comprises:
a control unit UC;
a power generator GEN that is regulated and controlled;
non-volatile memory MEM;
volatile memory RAM;
a communication unit COM;
a local alarm module ALM;
a light source LED (light emitting diode);
a sound source HP (speaker);
a screen ECR;
an autonomous power source BAT (such as a rechargeable battery or other charge accumulator);
a user interface IHM; and
an AC/DC converter CONV.

The converter is designed to convert the AC power received by the device between connections C3 and CN into DC power in order to supply the various electrical and electronic components of the device DIS mentioned above (the control unit UC, the screen ECR, the generator GEN, etc.).

The resistance of the earth connection for the exposed conductive parts can be measured in particular by means of an earth fault loop impedance technique consisting of:
injecting, into the earth connection for the exposed conductive parts, alternating current AC in phase with the voltage received via conductors C3 and CN; and
measuring a voltage generated between conductors CN and PE by the injected current (by measuring an instantaneous potential difference for peak values of the injected current when the latter is a sinusoidal alternating current, or if not by measuring the true RMS voltage).

On the basis of Ohm's law for example, the resistance (R_{det}) of the earth connection for the exposed conductive parts can be determined by the control unit UC based on the value of the injected current (Iᵢₙⱼ) and on the measured voltage value (Uₘₑₛ).

For this purpose, the generator GEN is regulated and controlled by the control unit UC to provide a stable alternating current at one or two levels (respectively 1 and 15 mA at peak value for example), the alternating current being injected in phase with the power received from conductors C3 and CN.

For the current injected by the generator GEN to be stable, one should ensure that the power provided by conductors C3 and CN is within the required voltage range. For example, this range may be between ten percent (10%) and six percent (6%) of a nominal voltage of 230 Volts.

In this respect, the unit UC may be adapted to measure the true RMS voltage (RMS) of the supply voltage between conductors C3 and CN (by being linked to an electronic circuit for measuring true RMS voltage that is connected between conductors C3 and CN for example). Thus, when the potential difference between conductors C3 and CN is not within the given power range (−10%/+6% of 230 volts), the unit CU can stop the voltage measurements and issue an alert (as detailed below). The issued alert may suggest maintenance by an operator of the electrical power distribution network, to restore a voltage within the required voltage range. If the detected voltage is zero, the issued alert indicates a power failure. The unit CU thus only performs voltage measurements on a stable current injected by the generator GEN at least at one regulated level.

The unit CU may also be implemented so that it measures the voltage between conductors CN and PE, generated by the current or currents injected into conductor PE. The potential difference may be measured in particular:
as an instantaneous potential difference for peak values of the injected current when the latter is a sinusoidal alternating current, or
as a true RMS voltage.

This potential difference or true RMS voltage may be measured by the unit UC via an analog-to-digital converter type of device connected to a voltage sensor placed between conductors PE and CN. The analog-to-digital converter is controlled by the unit.

In one possible embodiment, the determined resistance (R_{det}) is a function of the injected current (Iᵢₙⱼ) and of a measurement of the instantaneous voltage (Uₘₑₛ) that is performed simultaneously with the injection of current. We then obtain an overestimate for the resistance of the earth connection for the exposed conductive parts Ra, because the determined resistance (R_{det}) includes the resistance of the earth connection to neutral RN and of the neutral conductors LN and CN. In fact, by applying Ohm's law, we obtain:

R_{det}=RN+LN+CN+Ra=(Uₘₑₛ)/(Iᵢₙⱼ)

This method of calculation determines a resistance R_{det} which is an imprecise overestimate of the resistance of the earth connection for the exposed conductive parts Ra. It offers the advantage of overestimating the earth connection Ra, which introduces a safety margin (because RN+LN+CN+Ra is greater than the actual resistance value of the earth connection for the exposed conductive parts Ra). However, it can lead to false alarms (the earth resistance Ra actually being significantly below the threshold).

In a preferred embodiment, the determined resistance (R_{det}) is based on a current injected at two different levels of AC current (Iᵢₙⱼ), sinusoidal and in phase with the voltage received from conductors CN and C3 for the device DIS. These levels of current can be injected into the earth connection for the exposed conductive parts Ra. The measurement of two levels of instantaneous voltages (Uₘₑₛ) between conductors CN and PE, a measurement that is synchronized with peak values of the two levels of injected current, allows determining the resistance RN+Ra by application of Ohm's law:

R_{det′}=RN+Ra=|ΔUₘₑₛ|/|ΔIᵢₙⱼ|

In fact, this differential type of calculation determines a resistance R_{det′} which is also an overestimate of the resistance of the earth connection for the exposed conductive parts Ra. It includes the resistance of the earth connection to neutral RN of the distribution transformer T. It has the advantage, however, of subtracting the resistance of conductors LN and CN. As the supplemental resistance RN is relatively low, the overestimate of Ra introduces a reasonable margin of safety (as RN+R is only slightly higher than the true resistance value of the earth connection for the exposed conductive parts Ra).

In another possible variant, the determined resistance (R_{det″}) is also a function of the current injected at two different levels of AC current (Iᵢₙⱼ), sinusoidal and in phase with the voltage supplied to the device DIS received from conductors CN and C3. In addition, an average M(ΔUₘₑₛ)^{N} is determined. This average corresponds to the homogeneous values obtained for N instantaneous voltage measurements synchronized with the peak values of AC current injections at two levels. The average M(ΔUₘₑₛ)^{N} also allows determining the resistance (RN+Ra) by applying Ohm's law:

R_{det″}=RN+Ra=M(Uₘₑₛ)^{N}/|ΔIᵢₙⱼ|

This differential type of calculation determines a resistance R_{det″} which is based on an average of the homogeneous values of the measured voltages, said values forming the majority of the representative values. This average of the values eliminates the bad values inherent for example to electrical instabilities encountered in conductor LN during the current injections and the associated voltage measurements. The resistance R_{det″} is therefore more robustly determined, avoiding false alarms caused by momentary electrical instabilities during a measurement.

In another possible embodiment, X homogeneous values among Z values of R_{det}, R_{det′}, or R_{det″}, are averaged to obtain a representative value of the resistances measured over a specific period (over a day for example).

It should be noted that the data from measuring the voltages generated by the injected current may be stored:
temporarily in the volatile memory RAM for post-processing such as calculation of the average M(ΔUₘₑₛ)^{N};
for the long term in non-volatile memory MEM in order to log a history of voltage measurements between conductors C3 and CN.

The memory MEM is further intended for storing data relating to the value of the resistance threshold that is not to be exceeded. The memory MEM may also archive data relating to resistance values determined by the device DIS. This memory is non-volatile so that archived data is stored in a lasting manner, even in case of power loss to the memory.

For this purpose, the unit UC may be adapted for:
instructing the generator GEN to inject at least one defined level of current (or even two different levels of current) into the earth connection for the exposed conductive parts Ra via conductor PE, the current being injected in phase or in a constant phase difference with the power received via conductors CN and C3;
measuring via conductors PE and CN at least one voltage level generated by the current injected into the earth connection for the exposed conductive parts Ra (or two voltage levels when two currents of different levels are successively injected);
determining, via Ohm's law in particular, the sum of the resistance of the earth connection for the exposed conductive parts Ra and of the neutral RN (or even of conductors LN and CN in the case of a single voltage measurement synchronized with the peak value of the single current injection) as a function of the injected currents and the measured voltages;
storing in memory RAM for example ten instantaneous voltage measurements Uₘₑₛ or ten RN+Ra values in memory MEM in order to calculate the average of the majority of the most representative values taking into account for example the possible instability of the voltage observed on conductor LN during current injections into the earth connection for the exposed conductive parts Ra;
comparing the determined resistance or the average of the majority of the most representative determined resistances, to a predetermined threshold; and
issuing a warning signal when the determined resistance or the average resistance exceeds the predetermined threshold.

The unit UC may send commands to the generator GEN to cause one or two injections of AC current into the earth connection for the exposed conductive parts Ra (via conductor PE). As an illustration, the sinusoidal current injections are in phase with the voltage measured between conductors C3 and CN at a frequency of 50 Hz and are of an intensity at peak value of 1 and 15 mA. When injecting two currents at different levels, the currents may respectively be successively injected in five and three periods.

Preferably, the maximum intensity of the injected AC current is chosen to be less than the lowest trip current of the circuit breakers of the electrical system (which is typically 30 mA for a circuit breaker D of the low voltage panel TE), to avoid unwanted tripping when measuring the resistance of the earth connection for the exposed conductive parts Ra. It should be noted that it is possible for the measurements to trip a circuit breaker having a IΔn of 30 mA if there is already leakage current to ground in the circuit, which combines with the current of the measurement. In this case, the electrical system must be checked so that the faulty equipment can be repaired.

The unit UC may, for example, comprise an electronic circuit such as a microprocessor, microcontroller, or programmable logic device (FPGA, PLD, or other).

As mentioned above, the unit UC may be connected to known means of the prior art for measuring a potential difference or a true RMS voltage between conductors CN and PE on the one hand, and conductors CN and C3 on the other: voltage sensor, analog-to-digital converter, or other means.

Furthermore, the unit UC may be implemented so as to determine an average of:
voltage values measured and temporarily stored in volatile memory RAM;
resistance values determined and stored in non-volatile memory MEM.

The determined resistance values compared to the predetermined threshold may therefore be based on:
an instantaneous voltage measurement between conductors PE and CN that is synchronized with the peak value of a stable current injection into conductor PE;
a weighted average of the instantaneous voltage values measured between conductors PE and CN that are synchronized with peak values of stable current injections into conductor PE;
a weighted average of the instantaneous voltage values measured between conductors PE and CN that are synchronized with peak values of injections at two different levels of stable current into conductor PE;
a weighted average of the resistance values determined in accordance with one of the three above techniques.

For example, for ten instantaneous voltage measurements between conductors CN and PE which are synchronized with peak values of injected current having a maximum value of 1 mA and six instantaneous voltage measurements between conductors CN and PE which are synchronized with the peak value of an injected current having a maximum value of 15 mA, the unit CU determines the weighted average of the absolute values of the ten and six voltage measurements in order to calculate the difference, which always remains positive. From the difference obtained, it is then possible to determine the total resistance of the earth connections for the exposed conductive parts Ra and of the neutral RN by applying Ohm's law with the stable injected current that is of known value (because it is controlled by the unit UC).

Indeed, as the currents injected by the generator GEN are regulated to stable levels when the power received by the device DIS is within the given power range (−10%/+6% of 230 volts), the difference (ΔIᵢₙⱼ) between the levels of stable injected current is known. Typically, when the unit UC orders an injection of current by the generator GEN at a first level having a maximum value of 1 mA and an injection of current at a second level having a maximum value of 15 mA, the unit UC knows the difference between the levels of injected current (ΔIᵢₙⱼ), which is a maximum value of 14 mA.

Finally, the unit UC calculates the value RN+Ra then begins new current injections and new voltage measurements in order to obtain new RN+Ra values.

The unit UC may perform the voltage measurements, determine the overestimates for the resistance values of the earth connection for the exposed conductive parts Ra, and compare the determined resistance values with the predetermined threshold at different frequencies (such as the three frequencies described above). The second and third frequencies may be configured by the consumer or by an operator via the user interface IHM of the device which includes adjustment buttons. The values of these frequencies may also be stored in the non-volatile memory MEM of the device DIS.

In addition, the generator GEN and the unit UC may be arranged to detect that the current injected into the earth connection for the exposed conductive parts by the generator is zero. In this case, the electrical connection of the device or of the electrical panel TE may have been broken (hazardous situation for the user). The unit UC may then issue an alert so that an intervention can quickly restore the link to the earth connection for the exposed conductive parts of the device and of the panel TE where appropriate.

Furthermore, the unit UC may include a calendar and an internal clock that allows timestamping the data relating to the measured voltages and to the determined resistance. The archived data thus allow establishing a measurement history, so that changes over time in the measured voltages (between conductors CN and PE and between conductors C3 and CN) and in the overestimated resistance of the earth connection for the exposed conductive parts Ra can be established.

The unit UC can read the measurement data stored in memory MEM. From the accessed data, the unit UC can calculate a daily, monthly, or even annual average of the (overestimated) resistance of the earth connection for the exposed conductive parts Ra.

This average may also be stored in memory MEM, to give a global representation of the state of the overestimated earth connection for the exposed conductive parts Ra over a given period. This average may, for example, be displayed on the screen ECR or sent to the user via the communication unit COM.

When the switch INT1 is placed in the open position by the unit UC, the circuit supplying the terminal block BOR is opened which cuts power to the appliance AED.

The independent power source BAT may be either a Lithium-ion battery or a capacitor that is continuously charged by the power supply as long as it is present on conductors C3 and CN.

The device DIS then warns the user when a hazardous situation is detected via one or more overestimated measurements of the earth connection for the exposed conductive parts Ra. This hazardous situation results in cutting off power to the appliance (the switch is opened) and issuing a warning signal when the overestimated resistance of the earth connection for the exposed conductive parts Ra and of link PE is too high (greater than 100Ω for example). The user may be notified via various means that emit an alert signal upon receipt of the warning signal. The alert signal may be emitted in particular by:
the local alarm module ALM which may be in the form of the speaker HP (emitting a particular audio signal) and/or the light source LED (changing from a green light (if the value of the earth connection for the exposed conductive parts Ra is constant and less than 100Ω) to a red light (if the value of the earth connection to ground exceeds 100Ω). The light source LED displays an orange light when the value of the earth connection for the exposed conductive parts Ra is increasing but is below the threshold,
the screen ECR (displaying a warning message with the measured value), and/or
a remote entity which has received notification of an alert via the communication unit COM.

The screen ECR (which can typically be an LCD screen) may display different pieces of information, such as:
the nature of the alert (resistance threshold exceeded, network voltage outside the norm, power failure, etc.)
the date and time of the measurement of the earth connection for the exposed conductive parts or of the network voltage that generated the alert,
a preventive reminder message to test the earth connection for the exposed conductive parts Ra,
a request for intervention (which may be sent via the communication unit COM) to a repairman for verification or repair of the earth connection for the exposed conductive parts Ra;
a request for action (which may be sent via the communication unit COM) sent to a service provider asking it to measure the voltage and have the power distribution network operator adjust the supplied voltage if necessary.

The user is therefore warned of a hazardous situation on location by the light signal emitted by the light source LED, the audio signal emitted by the speaker HP, or by the information displayed on the screen of the device DIS. An acknowledgment button (present in the user interface IHM for example) turns off the audio warning.

The user may also be warned remotely by a notification sent from the communication unit COM upon receipt of the warning signal. This notification may be sent to the user via a web page, an email, or a phone application of the user. The unit COM may also receive notification from a remote entity such as the mobile phone of the user, for example to acknowledge an alert.

The unit COM may be a radio frequency communication module such as WiFi, Bluetooth, GSM, or some other module capable of transmitting data by radio to a remote entity (not represented in the figures).

The unit COM allows issuing warning signals or notifications to a remote entity such as a management center or to a communicating device of a user.

At the request of a remote entity, the unit COM may access data stored in the memory MEM and send them to the requesting entity. The requesting entity can thus process the data sent, in order to discover the exact variations over time in the resistance of the earth connection for the exposed conductive parts Ra or in the network voltage.

The user interface IHM (which may be in the form of buttons accessible to the user on the device DIS) may be adapted to allow:
configuring the device DIS (initializing the predetermined resistance threshold: 25, 50, 95 or 100Ω and above for example, choice of time intervals between each testing of the earth connection for the exposed conductive parts, entry of a cell phone number where alerts are to be sent, etc.),
acknowledge the audio and/or light warning,
browse the information displayed on the screen ECR.

Once configured, the predetermined threshold and the choice of time intervals between each resistance measurement are stored in the memory MEM of the device DIS.

Using the user interface IHM, it is also possible to update the calendar and clock of the unit UC and to access the data stored in the memory MEM. A user can thus display on the screen ECR a representation of variations over time of the network voltage and of the resistance of the earth connection for the exposed conductive parts Ra (as a graph, for example).

This history allows, via a smartphone of the user for example, showing a curve representing the evolution of the voltages measured by the device and the evolution of the earth connection for the exposed conductive parts Ra. This representation gives the user a quick overview and a regular monitoring of the data measured and calculated by the device. Monitoring the voltage supplied to the device may allow the user to prove to the power distributor that the voltage supplied is not within the required voltage range (−10%/+6% of a nominal voltage of 230 Volts).

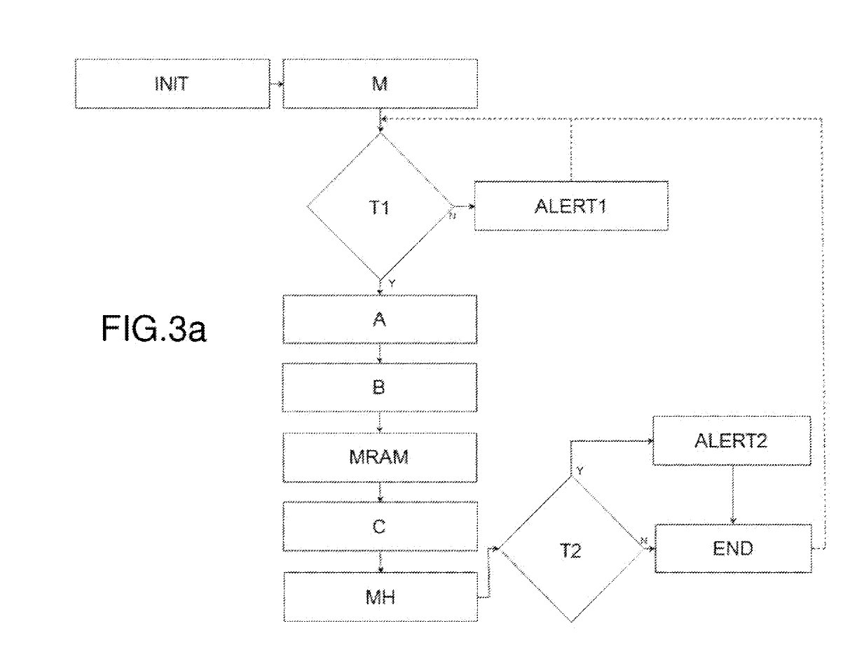

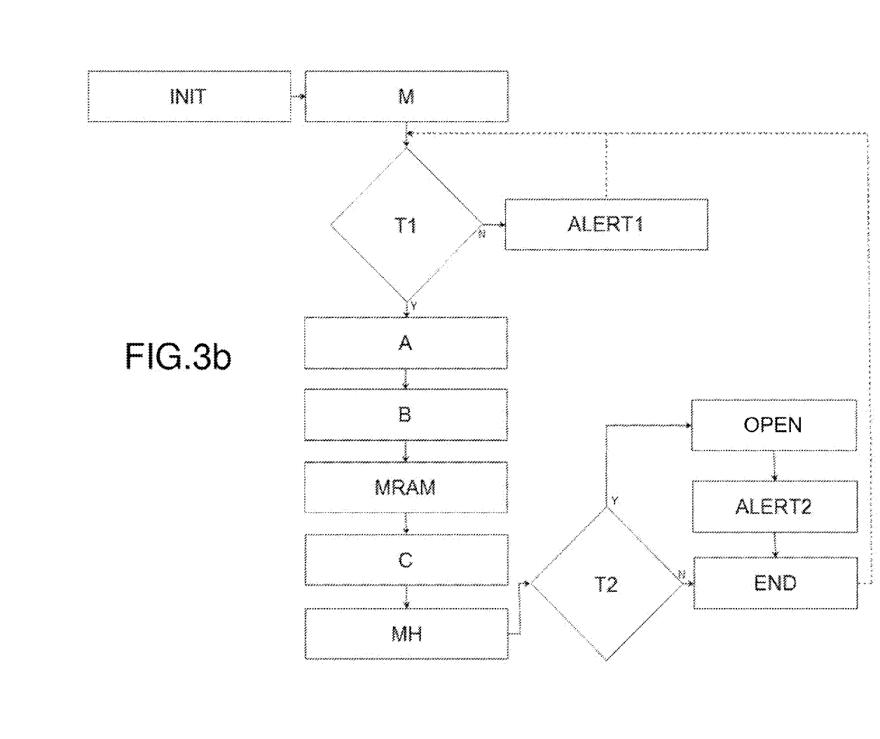

In addition, the memory MEM is adapted for storing a computer program comprising instructions readable by a processor of the unit UC. The processor can implement the method described below with reference to FIG. 3, when the program instructions are executed by the processor.

We now refer to FIG. 2b in which a second exemplary embodiment of the device DIS is represented. In this example, the device DIS further comprises:
a double-pole switch INT1 to cut power to the appliance AED, and
a single-pole reversing switch INT2, which ensures that the phase is properly received by the generator GEN according to its position (position 1 or position 2).

The unit UC may be adapted to:
set the position of the reversing switch INT2 to position 1 if a voltage close to the nominal voltage (230 volts, for example) is measured between conductors C3 and PE of the device DIS, and otherwise to position 2 of the switch INT2;
open switch INT1 when the determined resistance or the average resistance exceeds the predetermined threshold.

When the power on conductors C3 and CN disappears, the autonomous power source BAT takes over and supplies the converter CONV with power, allowing it to send a warning signal to the alarm module ALM and to the communication module COM.

We now refer to FIG. 3a in which is represented a first example of a flowchart containing steps of the electrical measuring method implemented by the device DIS.

In a first step INIT, the user or the device installer can adjust or update the value of the predetermined resistance threshold. He or she can also determine the chosen time interval between the different current injections or between two groups of multiple measurements (group of ten measurements, for example) of the resistance of the earth connection for the exposed conductive parts Ra.

In step M, the data of the predetermined threshold and/or of the time intervals selected and initialized in step INIT are stored in memory MEM.

In step T1, the unit UC can compare the supply voltage of the device DIS (provided by conductors C3 and CN) to a given nominal voltage range (between −10% and +6% of 230 Volts for example), a range corresponding to what is expected from the power distribution network operator and therefore corresponding to proper operation of the generator GEN.

If the supply voltage is not within this range (arrow N exiting step T1), then step ALERT1 issues a warning signal indicating that the measurements of the earth connection for the exposed conductive parts cannot be carried out and that the nominal voltage is not met. This alert may propose testing the supply voltage and requesting action by an operator of the electric power distribution network, to normalize the situation and restore the voltage to the power range expected by the device DIS. Upon activation of the ALERT1 step, confirmation by an operator (via an acknowledgment button on the user interface IHM of the device DIS or via a command received via the COM module) may be required to acknowledge the alert (particularly locally). Then, the flowchart can only be resumed by a specific button on the user interface IHM of the device DIS or by a command received via the COM module, which will repeat step T1. The rest of the steps of the method are therefore only carried out when the received power enables current injections at one or two stable and regulated levels, which then allows calculating the overestimated resistance of the earth connection for the exposed conductive parts Ra as a function of a single unknown, the value of the instantaneous voltage measured between conductors CN and PE and generated by the injected stable current (a voltage which, however, may be disrupted during measurement by variations in the neutral voltage as has already been mentioned above).

However, if the supply voltage is correct in step T1 (within the −10%/+6% range of the nominal voltage of 230 volts), then the unit UC carries out step A (Y arrow exiting step T1).

In step A, the unit UC orders the current generator GEN to inject alternating current AC (Iᵢₙⱼ) (at two different and successive sinusoidal levels for example) in phase with the supply voltage of the device DIS. These currents are injected into the earth connection for the exposed conductive parts Ra.

In one possible embodiment, an additional verification step may be performed (not represented in the figures), which verifies that the current injected into the earth connection for the exposed conductive parts is not zero. If it is zero, a warning signal may be issued so that the earth connection for the exposed conductive parts of the device and of the panel TE is tested and where necessary repaired by a specialist.

In step B, the unit UC then measures the voltage, i.e. the instantaneous voltage (Uₘₑₛ) generated or the true RMS voltage (Uₘₑₛ) generated, between conductors CN and PE, by the injected current (Iᵢₙⱼ).

In step MRAM, the data relating to the measured voltage values are stored temporarily in volatile memory RAM (which serves as working memory for calculating the average of the voltages measured during step C).

Steps A, B, and MRAM may be repeated at a predetermined frequency, for example every second, in order to carry out at least:
a predetermined number of successive current injections in phase with the voltage supplied to the earth connection for the exposed conductive parts Ra (sixteen injections for example, ten at a first current level and six at a second current level, injected in a stable manner over a period of 160 ms),
a predetermined number of instantaneous voltage measurements synchronized with the peak values of the current injections that generated them (typically sixteen corresponding measurements over a period of 160 ms),
the storage of the measured voltage values in volatile memory RAM.

In step C, the unit UC determines the resistance of the earth connection for the exposed conductive parts as a function of the injected current and of the measured voltage. To do this, the unit UC may extract the data temporarily stored in the volatile memory RAM. The resistance may be calculated on the basis of the resistances R_{det}, R_{det′}, or R_{det″} described above.

In step MH, data relating to the determined resistance values (R_{det}, R_{det′}, or R_{det″}) are archived and timestamped in non-volatile memory MEM.

At this stage, the unit UC may also store and timestamp the averages, calculated by the unit UC, in the non-volatile memory MEM for post-processing.

Steps C and MH may be successively repeated, typically every minute or every hour, in order to determine a resistance of the earth connection for the exposed conductive parts based on a weighted average of the resistance measurements already stored in memory.

In step T2, the unit UC compares the determined resistance value of the earth connection for the exposed conductive parts (R_{det}, R_{det′}, or R_{det″}), or the weighted average of this resistance, to the predetermined threshold value. For this comparison, the unit UC pulls the values needed from the non-volatile memory MEM.

If the resistance or the weighted average resistance does not exceed the predetermined threshold value (arrow N exiting step T2), the method ends (step END).

However, if the resistance or the weighted average resistance exceeds the predetermined threshold value (Y arrow exiting step T2), then step ALERT2 issues a warning signal to notify of a hazardous situation (risk of electrocution or electric shock if an individual has indirect contact).

Step T2 (and step ALERT2 if such applies) may be repeated at a frequency that is suitable for monitoring the evolution over time of the earth connection for the exposed conductive parts, for example daily or weekly. This lower frequency may be suitable for regularly calculating a weighted average of the resistances determined during a day, a week, or a month, and deriving a representative general value of the state of the earth connection over this period.

The method may remain stuck in step ALERT2 as long as an operator has not taken action (confirmation by acknowledgment button or remote control), then advances to step END once the safety of the earth connection has been verified and validated by a second local or remote action. This embodiment allows restarting the cycle of measurements of the earth connection for the exposed conductive parts Ra under safe electrical conditions.

After step END, the steps of the flowchart may be successively repeated to obtain a new measurement of the resistance of the earth connection for the exposed conductive parts Ra.

In addition to steps ALERT1 and ALERT2, steps (not represented in the figure) to communicate the alert to a remote entity may be implemented.

Furthermore, in addition to steps M, MRAM, and MH, steps of calculating the drift over time of the earth connection for the exposed conductive parts (not shown in the figure) may also be implemented, for example in order to control the orange light from the light source LED of the device DIS and generate a warning signal to a remote entity in case of an earth connection for the exposed conductive parts that is below the predetermined threshold but is increasing over time.

Another step may consist of sending, on request, data stored in memory MEM to a remote entity in steps M and MH.

In view of the above, it should be noted that the proposed device and method provide near real-time continuous monitoring of the overestimated resistance value of the earth connection for the exposed conductive parts Ra and of the conductor PE, as well as their possible drift over time in relation to the threshold, which may be 100Ω (or more) or slightly below the limit value (95Ω for example).

We now refer to FIG. 3b, in which is represented a second exemplary flowchart containing steps of the electrical measuring method implemented by means of the device DIS.

In this example, prior to step A, the voltage between conductors C3 and PE may be measured. If the measured voltage is close to the nominal voltage of 230 Volts, then the unit UC sets the reversing switch INT2 to position 1. Otherwise, the unit UC sets the reversing switch INT2 to position 2. This ensures that the generator GEN properly receives the phase of the power provided by the network RED.

In this second example, if the resistance value or weighted average resistance exceeds the predetermined threshold value (Y arrow exiting step T2), then step OPEN cuts power to the appliance AED by commanding the switch INT1 to change to the open position.

Next, step ALERT2 issues a warning signal when the measured resistance exceeds the predetermined threshold, in order to inform the user or the operator of a failure occurring at the appliance or in the earth connection.

The appliance is no longer supplied with power, so there is no risk of electric shock to the user in case of indirect contact with the appliance having improperly earthed exposed conductive parts.

At any time during execution of the method, if the supply voltage disappears on conductors C3 and CN entering the device DIS, then the unit UC issues an alert requesting that the fuses or circuit breaker of the electrical system be checked. Reappearance of the supply voltage on conductors C3 and CN then resumes the method at step T1.

The predetermined threshold may be an electrical resistance value set by the provisions of the NFC 15-100 and/or IEC 60364 standards, such as:
for an electric power network in France providing AC power:
   100Ω when the network environment is dry,
   50Ω when the network environment is wet,
   25Ω when the network is submerged,
for an electric power network in France providing DC power:
   240Ω when the network environment is dry,
   120Ω when the network environment is wet,
   60Ω when the network is submerged,

For added security, the predetermined threshold may be adjusted to a value slightly below the prescribed limits, for example 5% lower than the above values.

The device and method therefore protect users from hazardous indirect contact, said device operating continuously, with continuous or at least regular measurements (and without requiring the restrictive installation procedures of the prior art).

The device therefore significantly improves the safety of persons and property, and can further serve as a platform for implementing electrical safety services in the home and for requesting service to repair the earth connection for the exposed conductive parts and/or the connection of the appliance to this earth connection.

The invention has been described with reference to particular embodiments which are not limiting. The invention is of course not limited to the embodiment described by way of example, and extends to other variants. For example, the device may be incorporated into an appliance at manufacture or may be mounted on an existing appliance, the device then being connected to a dedicated electrical connection connected to the electrical system into which the appliance is plugged.

1. An electrical measuring device comprising at least:
a first electrical connection to an earth connection for exposed conductive parts of an electrical system connected to a main power network;
a second electrical connection to a neutral conductor of said network;
an alternating current generator regulated and controlled so as to inject an alternating current into said first electrical connection;
a control unit adapted for:
instructing said generator to inject regulated alternating current into said earth connection for exposed conductive parts via said first connection;
measuring, between said first and second connections, a voltage generated by said injected current;
determining a resistance of the earth connection for exposed conductive parts, based on at least one injected current value and on a voltage value measured for said injected current value;
comparing said determined resistance to a predetermined threshold; and
issuing a warning signal when said compared resistance exceeds the predetermined threshold.

2. The electrical measuring device according to claim 1, further comprising a switch to cut off power to an electrical appliance plugged into the electrical system, the control unit being adapted to open the switch when the compared resistance exceeds the predetermined threshold.

3. The electrical measuring device according to claim 1, further comprising an autonomous source of electrical power.

4. The electrical measuring device according to claim 1, wherein said injected current is regulated over time at least at a first level of current and a second level of current which are successively injected, the first and second levels of current being different.

5. The electrical measuring device according to claim 1, further comprising a third electrical connection to a phase conductor of said network, wherein the control unit is further adapted for:
measuring a true RMS voltage between said second and third connections;
comparing said true RMS voltage to a required voltage range; and
issuing a second warning signal when said true RMS voltage is not within said required voltage range.

6. The electrical measuring device according to claim 1, further comprising nonvolatile memory adapted for storing data relating to said determined resistance,
said resistance compared to said predetermined threshold being a weighted average value of the resistance of the earth connection for exposed conductive parts, calculated by the control unit from data stored in the memory.

7. The electrical measuring device according to claim 1, further comprising a communication unit for transmitting the first and/or second issued warning signal to a remote entity.

8. The electrical measuring device according to claim 7, wherein the communication unit is further adapted to transmit data stored in said memory when so requested.

9. An electrical home appliance plugged into an electrical system connected to a main power network, said system being provided with an earth connection for exposed conductive parts, said electrical appliance being connected to said earth connection for exposed conductive parts and being equipped with the electrical measuring device according to claim 1.

10. A method for electrical measurement via an electrical measuring device, said method comprising at least:
a) injecting regulated alternating current into an earth connection for exposed conductive parts of an electrical system connected to a main power network;
b) measuring, between the earth connection for exposed conductive parts and a neutral conductor of said network, a voltage generated by said injected current;
c) determining a resistance of the earth connection for exposed conductive parts, based on at least one injected current value and a voltage value measured for said injected current value;
d) comparing said determined resistance to a predetermined threshold; and
e) issuing a first warning signal when the measured resistance exceeds the predetermined threshold.

11. The electrical measuring method according to claim 10, further comprising cutting off the power to an electrical appliance plugged into the electrical system, when the compared resistance exceeds said predetermined threshold.

12. The electrical measuring method according to claim 10, wherein said current injection comprises a regulation of the current over time at least at a first level of current and a second level of current which are successively injected, the first and second levels being different.

13. The electrical measuring method according to claim 10, further comprising:
measuring a true RMS voltage between said neutral conductor and a phase conductor of said network;
comparing said true RMS voltage to a required voltage range; and
issuing a second warning signal when said true RMS voltage is not within said required voltage range.

14. The electrical measuring method according to claim 10, wherein said resistance compared to said predetermined threshold is a weighted average value calculated from measured resistance values of the earth connections for exposed conductive parts.

15. The electrical measuring method according to claim 10, wherein:
a) and b) are successively repeated at a first frequency;
c) is repeated at a second frequency;
d) and e) are successively repeated at a third frequency;
and wherein the first, second and third frequencies respectively have decreasing frequency values.

16. A non-transitory computer program product intended to be stored in a memory of an electrical measuring device, said computer program comprising instructions readable by a processor of a control unit of said device, said processor implementing the method according to claim 10 when said instructions are executed by said processor.
